(19) United States
(12) Patent Application Publication
(10) Pub. No.: US 2002/0153544 A1
(43) Pub. Date: Oct. 24, 2002

(54) Semiconductor device and its manufacturing method

(75) Inventor: Tamotsu Ogata, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 09/983,295

(22) Filed: Oct. 23, 2001

(30) Foreign Application Priority Data
Apr. 20, 2001 (JP) 2001-122068

(51) Int. Cl. H01L 27/108

(52) U.S. Cl. 257/296

(57) ABSTRACT

To improve a processibility of a contact hole by minimizing an aspect ratio of the contact hole to be connected to a semiconductor substrate from upper layers. A semiconductor device includes a capacitor that consists of a capacitor upper electrode, a capacitor lower electrode, and a capacitor dielectric film formed in a memory cell region on a semiconductor substrate through an interlayer insulating film, and a storage node pad electrode of a prescribed shape that consists of a film of the same layer as the capacitor lower electrode of the capacitor is formed on the interlayer insulating film in the regions other than the memory cell region. A contact plug to be connected to the semiconductor substrate from the upper layers can be connected to the semiconductor substrate through the storage node pad electrode, and the aspect ratio of the contact hole can be reduced.

### BACKGROUND OF THE INVENTION

1. Field of the Invention

The present invention relates to a semiconductor device and a manufacturing method thereof, more specifically to a semiconductor memory comprising a memory capacitor.

2. Background Art

In recent years, a semiconductor device comprising both a DRAM circuit and a logic circuit (e.g., a system LSI) has been manufactured. Such a semiconductor device is also known as an embedded DRAM (hereafter referred to as an eRAM). Through a use of an eRAM, system functions, which have heretofore been realized by the combination of a number of general purpose ICs, can be realized on one IC. A part of methods for manufacturing an eRAM will be described below referring to FIGS. 3 and 4.

Since the eRAM comprises both a DRAM circuit and a logic circuit, the eRAM has a region where the DRAM memory cell is formed (hereafter referred to as a DRAM circuit region) and a region where the logic circuit is formed (hereafter referred to as a logic circuit region). Here, the logic circuit region may be a peripheral circuit region of the DRAM circuit. In FIGS. 3 and 4, the DRAM circuit region is shown in the left-hand side, and the logic circuit region is shown in the right-hand side.

First, as shown in FIG. 3A, a gate oxide film 102 and a gate electrode 104 are formed on a semiconductor substrate 101 on which element activating and element isolating regions have been formed. Next, after forming diffused layers 103b of a low impurity concentration in a logic circuit region, an insulating film 105 such as a silicon nitride film is formed so as to cover the gate electrode 104. Thereafter, an appropriate ion implantation is performed on the surface region of the semiconductor substrate 101 to form diffused layers 103 in a DRAM circuit region, and diffused layers 103a of a high impurity concentration in the logic circuit region, and to form transistors in both regions. Here, the gate electrode 104 in the DRAM circuit region acts as a word line. Next, silicide layers 119 are formed of, for example, cobalt silicide (CoSi₂) using a method known as a salicide method so as to cover the prescribed region on the diffused layers 103 in the logic circuit region.

Next, after forming an interlayer insulating film 106 on the gate electrode 104, contact holes are formed in the DRAM circuit region by photolithography followed by dry etching, and the contact holes are filled with a polysilicon film to form pad electrodes 107 consisting of the polysilicon film.

In the DRAM circuit region, these pad electrodes 107 connect electrically a bit line and a capacitor lower electrode 112, formed in following steps, to the semiconductor substrate 101.

Next, after forming an interlayer insulating film 108 on the pad electrodes 107, tungsten wirings 109 and 110 acting as internal wirings are formed in the DRAM circuit region and the logic circuit region, respectively. The tungsten wiring 109 in the DRAM circuit region acts as a bit line, the tungsten wirings 110 in the logic circuit region receive contact plugs 117 formed in the following step, and are electrically connected to the silicide layers 119.

Next, as shown in FIG. 3B, an interlayer insulating film 111 is deposited, and a capacitor lower electrode 112 consisting of a polysilicon film is formed in the DRAM circuit region.

Next, as shown in FIG. 3C, a capacitor dielectric film 113 is deposited. The capacitor dielectric film 113 is formed of a dual-layer film, known as an ON film, formed by oxidizing a silicon nitride film to form a silicon oxide film on the surface. Thereafter, a capacitor upper electrode 114 consisting of a polysilicon film is formed in the DRAM circuit region.

Next, as shown in FIG. 4A, an interlayer insulating film 115 is deposited. After forming a contact hole in the interlayer insulating film 115, a contact plug 116 consisting of tungsten is formed in the DRAM circuit region, and contact plugs 117 also consisting of tungsten are formed in the logic circuit region. In the DRAM circuit region, the capacitor upper electrode 114 is electrically connected to the contact plug 116, while in the logic circuit region, the contact plugs 117 are electrically connected to the tungsten wirings 110.

Next, as shown in FIG. 4B, wiring layers 118 consisting of aluminum or copper to be connected to contact plugs 116 and 117 are formed. Thereafter, an interlayer film (not shown) is formed so as to cover the wiring layers 118, and wiring layers consisting of aluminum or copper are further formed on the interlayer film to form multi-layer wirings in the logic circuit region.

In the above-described conventional manufacturing method, however, the depth of the contact hole to embed the contact plug 116 in the DRAM circuit region is different from the depth of the contact holes to embed the contact plugs 117 in the logic circuit region. In the logic circuit region, in particular, since the contact holes to embed the contact plugs 117 must be passed through two insulating films, i.e., the contact interlayer insulating film 115 and the interlayer insulating film 111, the contact holes must be very deep as shown in FIG. 4A. Therefore, the aspect ratio of the contact holes to embed the contact plugs 117 increases, making dry etching for forming the contact holes very difficult. Moreover, it is required to increase the thickness of the capacitor lower electrode 112 in order to increase the capacity of the capacitor in the DRAM circuit region, and since the thickness of the contact interlayer insulating film 115 covering the capacitor lower electrode 112 increases accordingly, the contact holes to embed the contact plugs 117 become much deeper.

Furthermore, since the capacitor lower electrode 112 and the capacitor upper electrode 114 are formed only in the DRAM circuit region, level difference 120 equivalent to the sum of the thickness of the capacitor lower electrode 112 and the capacitor upper electrode 114 is eventually produced between the DRAM circuit region and the logic circuit region, as FIG. 4B shows. In particular, for increasing the capacity of the capacitor, the sum of the thickness of the capacitor lower electrode 112 and the capacitor upper electrode 114 must be increased, it is difficult to remove the level difference even if planarizing is performed after the contact interlayer insulating film 115 has been deposited. Such a lack of flatness has lowered the margin of dimensional accuracy by photolithography in forming delicate upper layer multi-layer wirings.

### SUMMARY OF THE INVENTION

The present invention is achieved to solve the above-described problems, and a first object of the present invention is to minimize the aspect ratio of contact holes to be connected to the semiconductor substrate from the upper layers to improve the processibility of the contact holes.

A second object of the present invention is to perform the patterning of wiring layers formed in upper layers in high accuracy by minimizing the level difference produced between regions in a semiconductor device having a memory cell and another region like an eRAM.

According to one aspect of the present invention, a semiconductor device comprises a capacitor that consists of an upper electrode, a lower electrode, and a dielectric film formed in a memory cell region on a semiconductor substrate through an interlayer insulating film. A conductive pattern of a prescribed shape that consists of a film of the same layer as the lower electrode of the capacitor is formed on the interlayer insulating film in the regions other than the memory cell region.

According to another aspect of the present invention, a method for manufacturing a semiconductor device comprises the following steps. Firstly a semiconductor element having a gate electrode and a pair of impurity diffused layers is formed in each of the first region and the second region on a semiconductor substrate. Secondly a first interlayer insulating film is formed on the semiconductor substrate including a region on the gate electrode. Thirdly an opening is formed in the first interlayer insulating film in each of the first and second regions. Fourthly a conductive film is formed on the first interlayer insulating film to fill the opening, and for electrically connecting the conductive film to the impurity diffused layer in each of the first and second regions. Fifthly the conductive film is patterned on the first interlayer insulating film for forming the lower electrode of a capacitor electrically connected to the impurity diffused layer in the first region, and for forming a conductive pattern of a prescribed shape electrically connected to the impurity diffused layer in the second region.

According to the present invention, since a conductive pattern of a prescribed shape consisting of a film of the same layer as the lower electrode of the capacitor is formed on the interlayer insulating film in the region other than the memory cell region, the conductive pattern can be used as the receiver of the contact plug connected from the above, an internal wiring, and the like. Since the contact plug to be connected to the semiconductor substrate from the upper layers can be connected to the semiconductor substrate through the conductive pattern, the aspect ratio of the contact hole can be lowered to improve processibility. Also, in the memory cell region and other regions, the flatness of the interlayer insulating film formed on the lower electrode and the conductive pattern can be improved.

Other and further objects, features and advantages of the invention will appear more fully from the following description.

### BRIEF DESCRIPTION OF THE DRAWINGS

FIGS. 1A to 1C are schematic sectional views showing a semiconductor device and a manufacturing method thereof according to an embodiment of the present invention.

FIGS. 2A and 2B are schematic sectional views showing a semiconductor device and a manufacturing method thereof according to an embodiment of the present invention.

FIGS. 3A to 3C are schematic sectional views showing a semiconductor device and a manufacturing method thereof according to the related art.

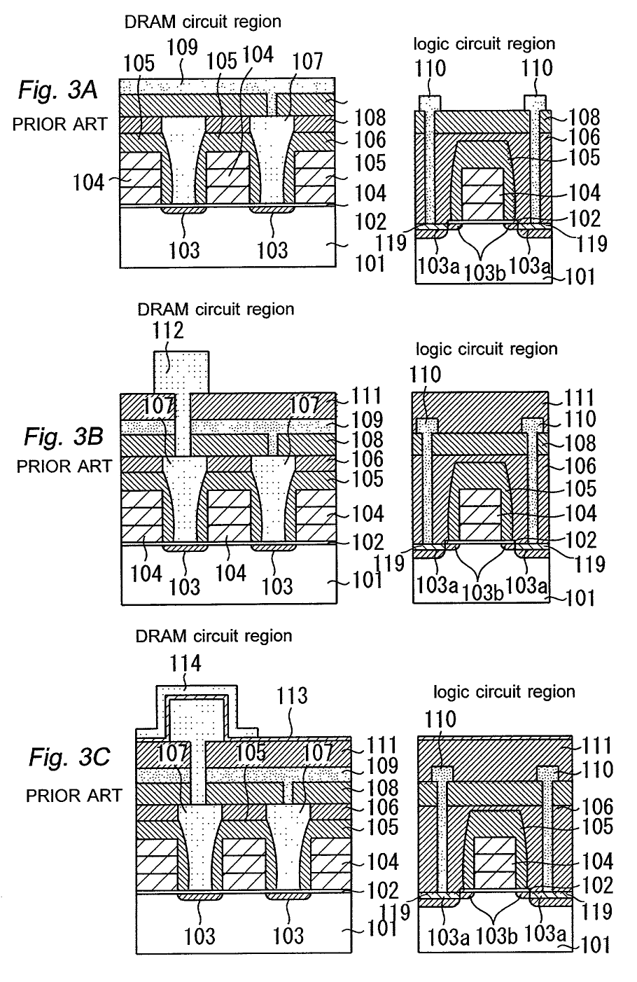

FIGS. 4A and 4B are schematic sectional views showing a semiconductor device and a manufacturing method thereof according to the related art.

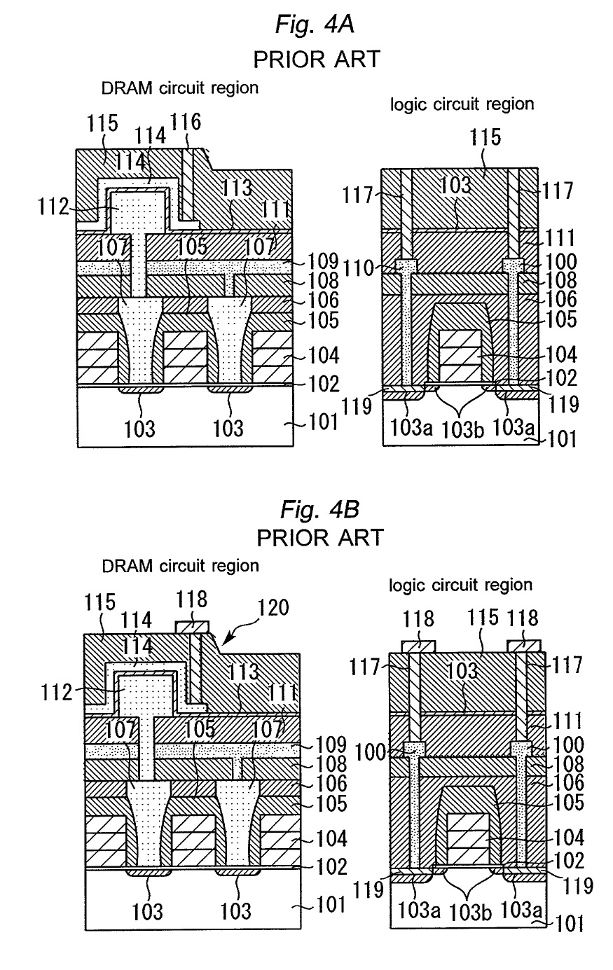

### DETAILED DESCRIPTION OF THE PREFERRED EMBODIMENTS

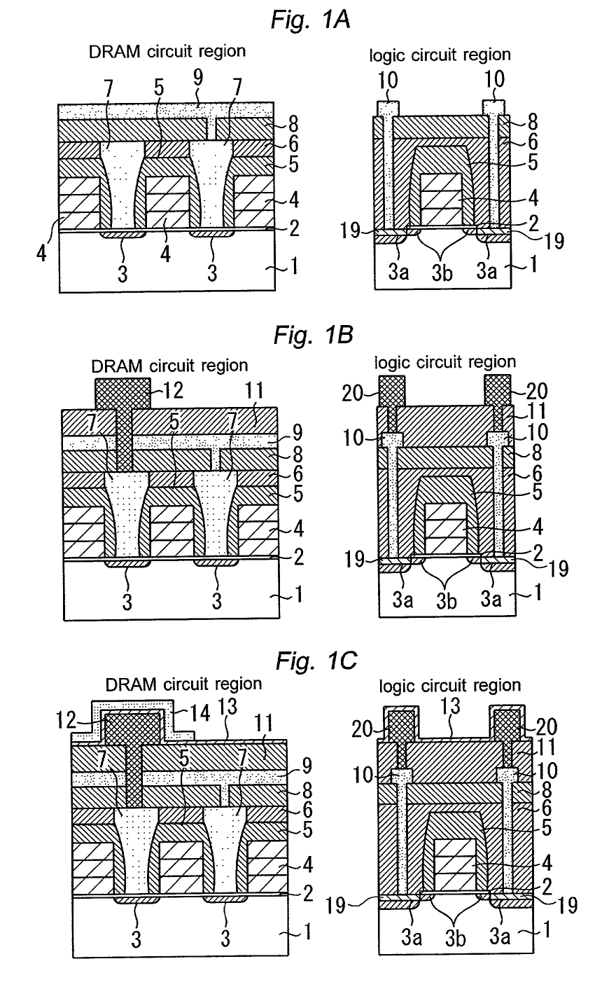

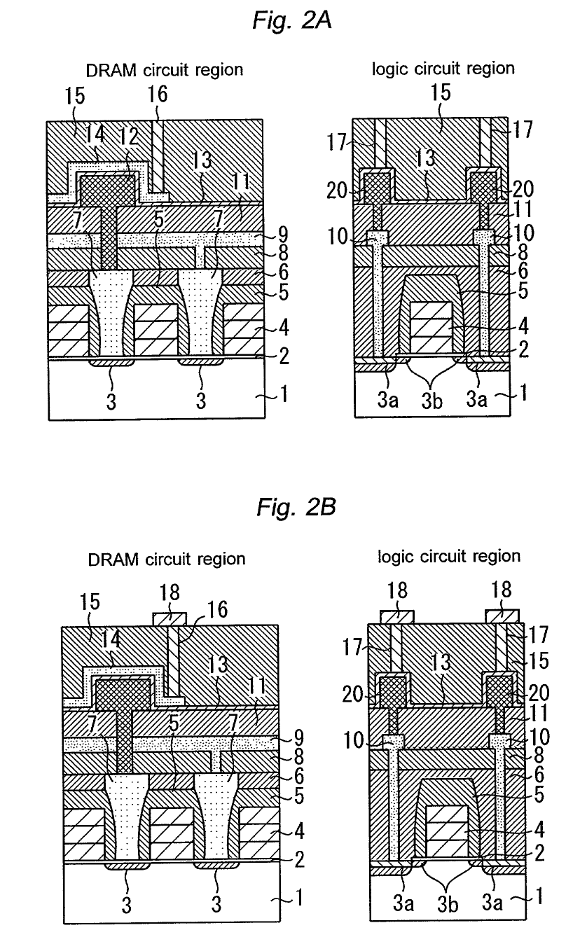

FIGS. 1 and 2 are schematic sectional views showing a semiconductor device and a manufacturing method thereof according to an embodiment of the present invention. The structure of a semiconductor device and the method for manufacturing thereof according to this embodiment will be described below referring to FIGS. 1 and 2. The semiconductor device of this embodiment is the one in which the present invention is applied to an eRAM comprising both a DRAM circuit and a logic circuit. In FIGS. 1 and 2, the DRAM circuit region is shown in the left-hand side, and the logic circuit region is shown in the right-hand side of the drawings.

First, as shown in FIG. 1A, a gate oxide film 2 and a gate electrode 4 are formed on a semiconductor substrate 1 on which element activating and element isolating regions have been formed. Next, after forming diffused layers 3b of a low impurity concentration in a logic circuit region by ion implantation using the gate electrode 4 as the mask, an insulating film 5 such as a silicon nitride film is formed so as to cover the gate electrode 4. Thereafter, an appropriate ion implantation is performed on the surface region of the semiconductor substrate 1 to form diffused layers 3 in a DRAM circuit region, and diffused layers 3a of a high impurity concentration in the logic circuit region, and to form transistors in both regions. Here, the gate electrode 4 in the DRAM circuit region acts as a word line. Next, silicide layers 19 are formed of, for example, cobalt silicide (CoSi₂) using a method known as a salicide method so as to cover the prescribed region on the diffused layers 3 in the logic circuit region.

Next, after forming an interlayer insulating film 6 on the gate electrode 4, contact holes are formed in the DRAM circuit region by photolithography followed by dry etching, and the contact holes are filled with a polysilicon film to form pad electrodes 7 consisting of the polysilicon film.

In the DRAM circuit region, these pad electrodes 7 connect electrically a bit line and a capacitor lower electrode 12, formed in following steps, to the semiconductor substrate 1.

Next, after forming an interlayer insulating film 8 on the pad electrodes 7, tungsten wirings 9 and 10 acting as internal wirings are formed in the DRAM circuit region and the logic circuit region, respectively. The tungsten wiring 9 in the DRAM circuit region acts as a bit line, the tungsten wirings 10 are electrically connected to the silicide layers 19 in the logic circuit region.

Next, as shown in FIG. 1B, an interlayer insulating film 11 is deposited, then the interlayer insulating film 11 and the underlying interlayer insulating film 8 in the DRAM circuit region are selectively removed to form a contact hole that reaches the pad electrode 7, and the interlayer insulating film 11 in the logic circuit region is selectively removed to form a contact hole that reaches the tungsten wiring 10. Then, a metal film is formed on the interlayer insulating film 11 to fill these contact holes, and the metal film is patterned on the interlayer insulating film 11. Thus, a capacitor lower electrode 12 consisting of the metal film is formed in the DRAM circuit region, and storage node pad electrodes (SN pad electrodes) 20 are formed in the logic circuit region.

In this case, the materials for the metal film for forming the capacitor lower electrode 12 and the storage node pad electrodes 20 include, for example, ruthenium (Ru), tungsten nitride (WN), titanium nitride (TiN), or platinum (Pt), and the film is formed using PVD or CVD methods. The capacitor lower electrode 12 thus formed is electrically connected to the pad electrode 7 consisting of polysilicon film. On the other hand, the storage node pad electrodes (SN pad electrodes) 20 receive contact plugs 21, which are formed in the following step. The storage node pad electrodes 20 are connected to tungsten wirings 10, which are bit lines in the logic circuit region, and are connected to silicide films 19 through the tungsten wirings 10. Here, in the logic circuit region, the metal film may be patterned on the interlayer insulating film 11 in a wiring shape to use as an internal wiring.

Next, as shown FIG. 1C, a capacitor dielectric film 13 is deposited. The capacitor dielectric film 13 is formed from a material such as tantalum oxide (Ta₂O₅). Thereafter, a capacitor upper electrode 14 consisting of a metal film is formed in the DRAM circuit region. The materials for the metal film composing the capacitor upper electrode 14 include, for example, ruthenium (Ru), tungsten nitride (WN), titanium nitride (TiN), or platinum (Pt). The film is formed using PVD or CVD method, and is patterned in the electrode shape using photolithography followed by dry etching. The capacity of the capacitor can be increased by composing both the capacitor upper electrode 14 and the capacitor lower electrode 12 with a metal film, such as a ruthenium film, and coupling these electrodes capacitively through a tantalum oxide film (capacitor dielectric film 13) having a high dielectric constant.

Next, as shown in FIG. 2A, a contact interlayer insulating film 15 is deposited. After forming contact holes in the contact interlayer insulating film 15, a tungsten film is formed to fill these contact holes to form a contact plug 16 consisting of tungsten film in the DRAM circuit region, and at the same time, contact plugs 17 also consisting of tungsten film are formed in the logic circuit region. In the DRAM circuit region, the capacitor upper electrode 14 is electrically connected to the contact plug 16, while in the logic circuit region, the contact plugs 17 are electrically connected to the storage node pad electrodes 20.

Next, as shown in FIG. 2B, wiring layers 18 consisting of aluminum, copper, or the like to be connected to contact plugs 16 and 17 are formed on the contact interlayer insulating film 15. Thereafter, an interlayer film (not shown) is formed so as to cover the wiring layers 18, and wiring layers consisting of aluminum, copper, or the like are further formed on the interlayer film to form multi-layer wirings in the logic circuit region.

According to the present invention, as described above, the capacitor lower electrode 12 and the capacitor upper electrode 14 in the DRAM circuit region are composed of metal films such as ruthenium films, and conductive patterns, such as wiring patterns and electrode patterns, are formed using the same layer as the metal film composing the capacitor lower electrode 12 in the logic circuit region. Thereby, conductive patterns, such as storage node pad electrodes 20, can be formed also in the logic circuit region in the same process as the process for forming the capacitor lower electrode 12. When the storage node pad electrodes 20 are formed as the conductive pattern, the storage node pad electrodes 20 can be used as the receiver of the contact plugs 17. Therefore, the contact plugs 17 can be connected to the underlying tungsten wirings 10 through the storage node pad electrodes 20, and the depth of contact holes to embed the contact plugs 17 can be shallowed by the thickness (height) of the storage node pad electrodes 20. Therefore, the aspect ratio of the contact holes can be decreased to improve the processibility of etching significantly, and the highly accurate wiring suitable for downsizing can be formed.

Also, when the internal wiring pattern is formed using the same layer as the capacitor lower electrode 12 in the logic circuit region, at least a part of the process for forming the wiring layers in the logic circuit region can be omitted. Therefore, the process can be simplified and the manufacturing costs can be lowered. Also, when the internal wiring pattern is formed, the aspect ratio of the contact holes connected from the above can be decreased, and the contact holes can be formed easily.

Furthermore, since the storage node pad electrodes 20 having the same thickness as the thickness of the capacitor lower electrode 12 are formed in the logic circuit region, in particular, the formation of level difference on the upper surface of the contact interlayer insulating film 15 in the vicinity of the interface between the DRAM circuit region and the logic circuit region can be prevented. Therefore, when the wiring layer of aluminum, copper, or the like is formed above the contact interlayer insulating film 15, the accuracy of patterning by photolithography can be improved, and further downsizing can be achieved.

Also, in the logic circuit region, since the storage node pad electrode 20 is electrically connected to the impurity diffused layer 3a on the semiconductor substrate 1 through the tungsten wiring 10, which is a bit line, it is not required to form a new pad electrode for connecting the storage node pad electrode 20 to the impurity diffused layer 3a in the logic circuit region, where no pad electrodes are normally formed. Therefore, the connection of the storage node pad electrode 20 to the semiconductor substrate 1 through the bit line avoids the complexity of the manufacturing process.

Since the present invention is constituted as described above, the following effects can be achieved.

Since a conductive pattern of a prescribed shape consisting of a film of the same layer as the lower electrode of the capacitor is formed on the interlayer insulating film in the region other than the memory cell region, the conductive pattern can be used as the receiver of the contact plug connected from the above, an internal wiring, and the like. Since the contact plug to be connected to the semiconductor substrate from the upper layers can be connected to the semiconductor substrate through the conductive pattern, the aspect ratio of the contact hole can be lowered to improve processibility. Also, in the memory cell region and other regions, the flatness of the interlayer insulating film formed on the lower electrode and the conductive pattern can be improved.

Since the contact plug to be electrically connected from the upper layers is connected to the bit line through the conductive pattern, the aspect ratio of the contact hole can be lowered. Also, since the conductive pattern is connected to the bit line, it is not required to form the electrode pad for connecting the conductive pattern to the semiconductor substrate, and the process can be simplified.

Since the conductive pattern is formed in a wiring shape, the internal wiring can be formed using the same layer as the lower electrode of the capacitor in the regions other than the memory cell region, and the number of process steps can be decreased.

Since the plane shape of the conductive pattern is made in the electrode pad shape, the conductive pattern can be used as the receiver of the contact plug to be connected from the upper layers, and the aspect ratio of the contact hole can be lowered to improve processibility.

Since the thickness of the conductive pattern is made substantially the same as the thickness of the lower electrode, the flatness of the interlayer insulating film formed on the lower electrode and the conductive pattern can be improved in the memory cell region and other regions.

Since the memory cell region is used as the DRAM circuit region, and the regions other than the memory cell region are used as the logic circuit region, the level difference in the vicinity of the interface between the DRAM circuit region and the logic circuit region can be minimized.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-122068, filed on Apr. 20, 2001 including specification, claims, drawings and summary, on which the Convention priority of the present application is based, are incorporated herein by reference in its entirety.

1. A semiconductor device comprising a capacitor that consists of an upper electrode, a lower electrode, and a dielectric film formed in a memory cell region on a semiconductor substrate through an interlayer insulating film,
wherein a conductive pattern of a prescribed shape that consists of a film of the same layer as said lower electrode of said capacitor is formed on said interlayer insulating film in the regions other than said memory cell region.

2. The semiconductor device according to claim 1, further comprising:
a semiconductor element that comprises a gate electrode and a pair of impurity diffused layer formed on said semiconductor substrate in the regions other than said memory cell region; and
a bit line connected to said impurity diffused layer,
wherein a contact plug electrically connected to said bit line from the above is connected to said bit line through said conductive pattern.

3. The semiconductor device according to claim 1, wherein said conductive pattern is formed in a wiring shape.

4. The semiconductor device according to claim 1, wherein the plane shape of said conductive pattern is an electrode pad shape.

5. The semiconductor device according to claim 1, wherein a thickness of said conductive pattern is substantially identical to a thickness of said lower electrode on said interlayer insulating film.

6. The semiconductor device according to claim 1, wherein said memory cell region is a DRAM circuit region, and the region other than said memory cell region is a logic circuit region.

7. A method for manufacturing a semiconductor device, comprising,
a first step of forming a semiconductor element having a gate electrode and a pair of impurity diffused layers in each of the first region and the second region on a semiconductor substrate,
a second step of forming a first interlayer insulating film on said semiconductor substrate including a region on said gate electrode,
a third step of forming an opening in said first interlayer insulating film in each of said first and second regions,
a fourth step of forming a conductive film on said first interlayer insulating film to fill said opening, and for electrically connecting said conductive film to said impurity diffused layer in each of said first and second regions, and
a fifth step of patterning said conductive film on said first interlayer insulating film for forming the lower electrode of a capacitor electrically connected to said impurity diffused layer in said first region, and for forming a conductive pattern of a prescribed shape electrically connected to said impurity diffused layer in said second region.

8. The method for manufacturing a semiconductor device according to claim 7, further comprising, after said fifth step,
a sixth step of forming a second interlayer insulating film on said conductive pattern,
a seventh step of forming an opening that reaches said conductive pattern on said second interlayer insulating film, and
an eighth step of filling said opening, and for forming a contact plug electrically connected to said conductive pattern.

9. The method for manufacturing a semiconductor device according to claim 7, wherein, in said fifth step, said conductive film is patterned to a wiring shape to form said conductive pattern.

10. The method for manufacturing a semiconductor device according to claim 7, wherein, in said fifth step, said conductive film is patterned to an electrode-pad shape to form said conductive pattern.

11. The method for manufacturing a semiconductor device according to claim 7, further comprising, prior to said second step, a ninth step for forming a bit line connected to said impurity diffused layer in said second region,
wherein in said third step, said opening is formed so as to reach said bit line in said second region, and
in said fourth step, said conductive film is electrically connected to said impurity diffused layer through said bit line.

12. The method for manufacturing a semiconductor device according to claim 7, further comprising, after said fifth step,
a tenth step of forming a dielectric film on said lower electrode in said first region, and
an eleventh step of forming an upper electrode of the capacitor on said dielectric film.

13. The method for manufacturing a semiconductor device according to claim 7, wherein said first region is made a DRAM circuit region, and said second region is made a logic circuit region.
